(19) United States
(12) Patent Application Publication
(10) Pub. No.: US 2025/0393220 A1
(43) Pub. Date: Dec. 25, 2025

(54) MEMORY DEVICE WITH A THREE-DIMENSIONAL VERTICAL STRUCTURE AND DRIVING METHOD THEREOF

(71) Applicant: Micron Technology, Inc., Boise, ID (US)

(72) Inventors: Andrea Martinelli, Bergamo (BG) (IT); Christophe Vincent Antoine Laurent, Arcore (MB) (IT); Ferdinando Bedeschi, Biassono (MB) (IT); Efrem Bolandrina, Fiorano al Serio (IT)

(21) Appl. No.: 18/880,422

(22) PCT Filed: Jan. 17, 2023
(86) PCT No.: PCT/IB2023/050406

§ 371 Date: Dec. 31, 2024

(51) Int. Cl. H10B 63/00; G11C 5/06; G11C 13/00; H10B 63/10

(52) U.S. Cl. CPC H10B 63/84; G11C 5/063; G11C 13/0026; H10B 63/30; H10B 63/10

(57) ABSTRACT

It is disclosed a memory device comprising: a plurality of pillars extending through a plurality of levels of a memory array; one or more memory cells of the memory array coupled with a respective pillar and a respective word line at each level; a digit line; a plurality of TFTs, each TFT being configured to selectively couple the digit line with a respective pillar, wherein the plurality of pillars, the one or more memory cells and the plurality of thin film transistors are positioned in a first area of the memory array, and wherein the digit line extends in the first area and at least partially in a second area outside the first area; a driver for the digit line. The driver comprises a first TFT, a second TFT and a pillar, wherein the first TFT, the second TFT and the pillar are positioned in the second area.

### CROSS REFERENCE

The present Application for Patent is a 371 national phase filing of International Patent Application No. PCT/IB2023/050406 by Martinelli et al., entitled “MEMORY DEVICE WITH A THREE-DIMENSIONAL VERTICAL STRUCTURE AND DRIVING METHOD THEREOF,” filed Jan. 17, 2023, assigned to the assignee hereof, and expressly incorporated by reference in its entirety herein.

### TECHNICAL FIELD

The present disclosure generally relates to the field of electronics.

More in particular, the present disclosure concerns a memory device with a three-dimensional (3D) vertical structure and a method for driving the digit lines of the 3D vertical structure memory device.

### BACKGROUND

Electronic memory devices (hereinafter, briefly referred to as “memory devices”) are widely used to store data in various electronic devices such as tablets, computers, wireless communication devices (e.g., smartphones), cameras, digital displays, and the like.

Memory devices are widely used to store information in various electronic devices such as computers, wireless communication devices, cameras, digital displays, and the like.

Information is stored by programing different states of a memory device. For example, binary devices most often store one of two states, often denoted by a logic 1 or a logic 0. In other devices, more than two states may be stored.

To access the stored information, a component of the device may read, or sense, at least one stored state in the memory device.

To store information, a component of the device may write, or program, the state in the memory device.

Various types of memory devices exist, including magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), other chalcogenide-based memories, and others.

Memory devices may be volatile or non-volatile.

Memory devices with cross-point architecture are known for example from WO 2021/186199 A1 and WO 2021/240203, wherein the memory cells are arranged in a three-dimensional (3D) vertical array including word lines and digit lines.

Each memory cell includes a dielectric material and a storage element material. The storage element material is for example chalcogenide material, which is a self selecting storage element material (e.g., a material that may serve as both a select device and a storage element).

A memory cell is formed at a topological cross-point between a word line and a digit line orthogonal to each other, wherein a memory cell is accessed through a word line and a digit line which is in a form of conductive pillar extending vertically.

A pillar selection layer is formed under the memory array and it has thin film transistors (TFTs) formed therein for accessing the memory cells, wherein a TFT is associated to each pillar for selecting a digit line.

The cross-point architecture may offer relatively high-density data storage with lower production costs compared to other memory architectures. For example, the cross-point architecture may have memory cells with a reduced area and, resultantly, an increased memory cell density compared to other architectures.

Decoding circuitry for word lines and digit lines are formed in the substrate under the 3D array of memory cells, in particular using CMOS circuitry under the array, thus reducing the space available for placing other circuitry for operating the memory device, such as sense amplifiers and biasing circuits.

Solutions for saving space in the memory array region may be desired.

### SUMMARY

An object of the present disclosure is to provide an improved memory device with a 3D structure as defined in the enclosed claims.

Another object of the present disclosure is to provide an efficient method for driving the digit lines of a memory device with 3D vertical structure as defined in the enclosed claims.

The memory device and driving method of the present disclosure have the following advantages:
the area available under the 3D array of memory cells for placing circuitry for operating the memory device may be increased;
the driving capability of the digit lines activating a plurality of memory cells simultaneously may be increased;
the routing congestion of digit lines may be reduced.

In a first aspect, one embodiment of the present disclosure is a memory device comprising a plurality of pillars extending through a plurality of levels of a memory array, comprising one or more memory cells of the memory array coupled with a respective pillar and a respective word line at each level of the plurality of levels, comprising a digit line, comprising a plurality of thin film transistors, each thin film transistor being configured to selectively couple the digit line with a respective pillar, wherein the plurality of pillars, the one or more memory cells and the plurality of thin film transistors are positioned in a first area of the memory array, and wherein the digit line extends in the first area and at least partially in a second area outside the first area, and comprises a driver for the digit line. The driver comprises a first thin film transistor, a second thin film transistor and a pillar, wherein the first thin film transistor, the second thin film transistor and the pillar are positioned in the second area.

In one embodiment, the digit line is coupled to the first thin film transistor and to the second thin film transistor.

In one embodiment, the first thin film transistor is coupled between the digit line and an end portion of said pillar, another end portion of said pillar being configured to be coupled to a source of an inhibit voltage.

In one embodiment, the first thin film transistor comprises a first gate terminal for driving the first thin film transistor, the first gate terminal coupled to a first gate line in the second area in a second direction substantially orthogonal to a first direction of the digit line.

In one embodiment, the second thin film transistor is coupled between the digit line and a conductive line configured to be biased to an access voltage.

In one embodiment, the second thin film transistor comprises a second gate terminal for driving the second thin film transistor, the second gate terminal coupled to a second gate line in the second area in a second direction substantially orthogonal to a first direction of the digit line.

In one embodiment, the memory device comprises a further digit line, a further driver for the further digit line comprising a third thin film transistor, a fourth thin film transistor and a further pillar, the third thin film transistor, the fourth thin film transistor and the further pillar being positioned in the second area, wherein the third thin film transistor comprises a third gate terminal for driving the third thin film transistor, the third gate terminal coupled to a third gate line, the fourth thin film transistor comprises a fourth gate terminal for driving the fourth thin film transistor, the fourth gate terminal coupled to a fourth gate line, wherein the third thin film transistor is coupled between the further digit line and an end portion of said further pillar, another end portion of said further pillar being configured to be coupled to a source of an inhibit voltage.

In one embodiment, the first thin film transistor and said pillar form a first electrical path between the digit line and the source of the inhibit voltage, the memory device further comprising a third thin film transistor and a further pillar coupled between the digit line and the source of the inhibit voltage, the third thin film transistor and the further pillar forming a second electrical path in parallel connection to the first electrical path.

In one embodiment, the memory device further comprises a fourth thin film transistor coupled between the digit line and the conductive line in parallel connection to the second thin film transistor.

In one embodiment, the memory device further comprises a gate line biasing circuit configured to drive a gate line coupled to the first and/or the second thin film transistor, wherein the gate line circuit is positioned in the second area.

In one embodiment, the second area is adjacent to the first area, the first area comprising active cells and the second area comprising inactive cells.

In one embodiment, the memory device further comprises a voltage supply generator configured for generating an access voltage, wherein the voltage supply generator is arranged in a portion of the first area.

In a second aspect, one embodiment of the present disclosure is a method for driving digit lines in a memory device. The method comprises the step of providing a plurality of memory cells at cross-points of word lines, on a plurality of levels of a memory array, and a plurality of conductive pillars extending through the plurality of levels, wherein a plurality of thin film transistors are each coupled between the digit line and a respective pillar, wherein the plurality of memory cells and the plurality of thin film transistors are positioned in a first area of the memory array, and wherein the digit line extends in the first area and at least partially in a second area outside the first area. The method further includes the step of selectively enabling a first thin film transistor, coupled between the digit line and an end portion of a pillar, to bias the digit line to an inhibit voltage applied to another end portion of the pillar, and a second thin film transistor, coupled between the digit line and a conductive line, to bias the digit line to an access voltage applied to the conductive line, wherein the first thin film transistor, the second thin film transistor and the pillar are positioned in the second area.

In one embodiment, the driving method further includes coupling another end portion of said pillar to a source of an inhibit voltage.

In one embodiment, the driving method further includes coupling a first gate line in the second area to a first gate terminal of the first thin film transistor, wherein the first gate line extends in a second direction substantially orthogonal to a first direction of the digit line.

In one embodiment, the driving method further includes coupling a second gate line in the second area to a second gate terminal of the second, wherein the second gate line extends in a second direction substantially orthogonal to a first direction of the digit line.

In one embodiment, the second area is adjacent to the first area, the first area comprising active cells and the second area comprising inactive cells.

In a third aspect, one embodiment of the present disclosure is a method for manufacturing a memory device. The manufacturing method comprise the steps of: a) forming a plurality of conductive word lines, electrically insulated from each other, in a plurality of levels; b) forming a plurality of conductive pillars through the plurality of levels, the plurality of pillars comprising active pillars in a first active area of a memory array and dummy pillars in an second area of the memory array adjacent to the first active area; c) forming memory cells at cross-points of word lines and the plurality of pillars; d) forming a plurality of conductive digit lines, electrically insulated from each other, in the first active area and extending, at least partially, into the second area; e) forming, in the first active area and in the second area, a plurality of thin film transistors, each thin film transistor in the first active area being coupled between a respective digit line and a respective pillar of the plurality of pillars; f) forming a digit line driver in the second area. The digit line driver comprises at least one first thin film transistor coupled between a respective digit line and a respective dummy pillar having an end coupled to a source of a inhibit voltage, and comprises at least one second thin film transistor coupled between the respective digit line and a respective conductive line coupled to an access voltage.

In one embodiment, the manufacturing method further comprises forming a plurality of conductive gate lines, the gate lines comprising first gate lines coupled to gate terminal of each thin film transistor in the first active area, and second gate lines selectively coupled to one of the first thin film transistor or the second thin film transistor in the second area.

In one embodiment, forming the digit line driver of the manufacturing method further comprises forming a conductive material in electrical contact of one end of a conductive channel of each thin film transistor of the plurality of thin film transistors in the first active area and in the second area, and patterning the conductive material so as to form the respective conductive line coupled to one end of a conductive channel of the at least one second thin film transistor, and conductive elements on respective ends of conductive channels of the at least one first thin film transistor and the each thin film transistor in the active area.

### BRIEF DESCRIPTION OF THE DRAWINGS

FIG. 1 schematically shows an example of a memory device that supports driving of digit lines according to examples disclosed herein.

FIG. 2 schematically shows a top view of an example of a memory device that supports driving of digit lines according to examples disclosed herein.

FIGS. 3A and 3B schematically shows side views of an example of a memory device that supports driving of digit lines according to examples disclosed herein.

FIG. 4 schematically shows a layout of a memory device having a first area with 3D array of active memory cells and having a second dummy area of inactive memory cells, that supports driving of digit lines according to examples disclosed herein.

FIG. 5 schematically shows more in detail a top view of a portion of the first and second areas of FIG. 4.

FIGS. 6A, 6B and 6C show side section views relative to cut planes D-D, E-E and F-F of FIG. 5.

FIG. 7A-7B show electrical schemes of a digit line driver that supports driving of digit lines according to examples disclosed herein.

FIG. 8 shows a flowchart of a driving method that supports driving of digit lines according to examples disclosed herein.

### DETAILED DESCRIPTION

In some memory architectures, a memory cell may be accessed (e.g., written to, read from) based on an electrical current through the memory cell. For example, in some material memory architectures (e.g., memory architectures implementing one or more chalcogenide memory elements), a logic state may be written to a memory cell based on a current driven through the memory cell (e.g., an amount of current, a direction of current), and a logic state may be read from the memory cell based on a current (e.g., a presence of current, an absence of current, an amount of current) through the memory cell based on or in response to a read bias across the memory cell. In some such architectures, memory cells may be accessed based on various decoding procedures or architectures, which may involve transistors or other switching components to access selected memory cells in accordance with an addressing scheme. For example, for accessing certain memory cells, a voltage may be applied to gates of some transistors for coupling some conductive structures (e.g., for coupling access lines across a channel of the transistors), and the voltage may not be applied to gates of some other transistors to maintain an isolation between other conductive structures.

For a given set of memory cells (e.g., a section of memory cells, a tile of memory cells), a driver associated with driving access currents through the memory cells may be associated with a relatively higher current than a driver associated with coupling conductive structures (e.g., a driver associated with biasing transistor gates, a driver associated with activating transistor channels) in accordance with an addressing scheme of the set of memory cells. In some examples, a driver associated with a relatively higher current may be associated with a relatively larger footprint of a memory die, or a relatively higher current density through interconnecting structures such as socket regions, or both a relatively larger footprint and a relatively higher current density, among other differences compared with a driver associated with a relatively lower current.

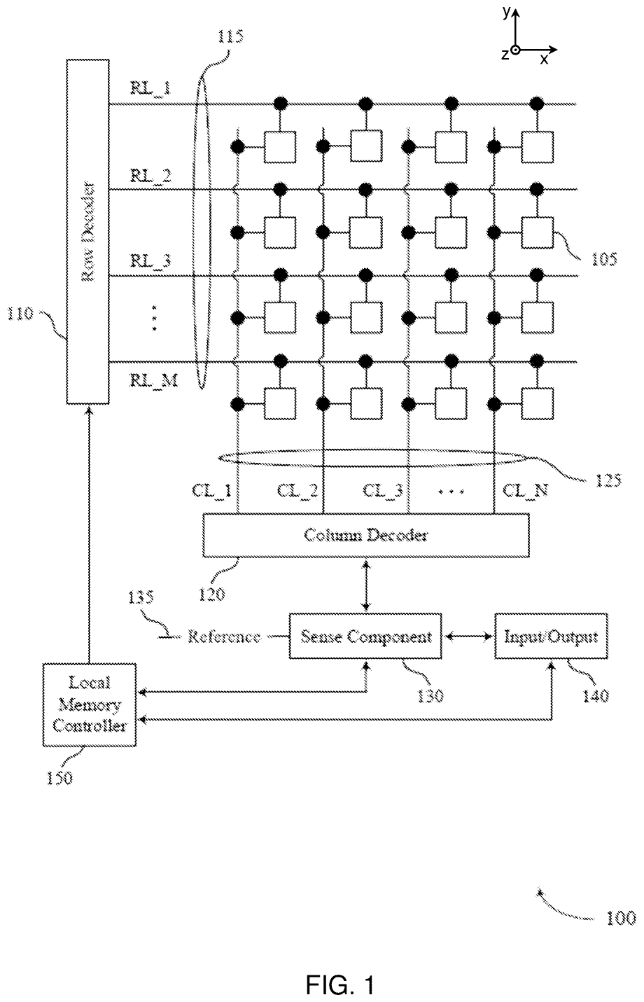

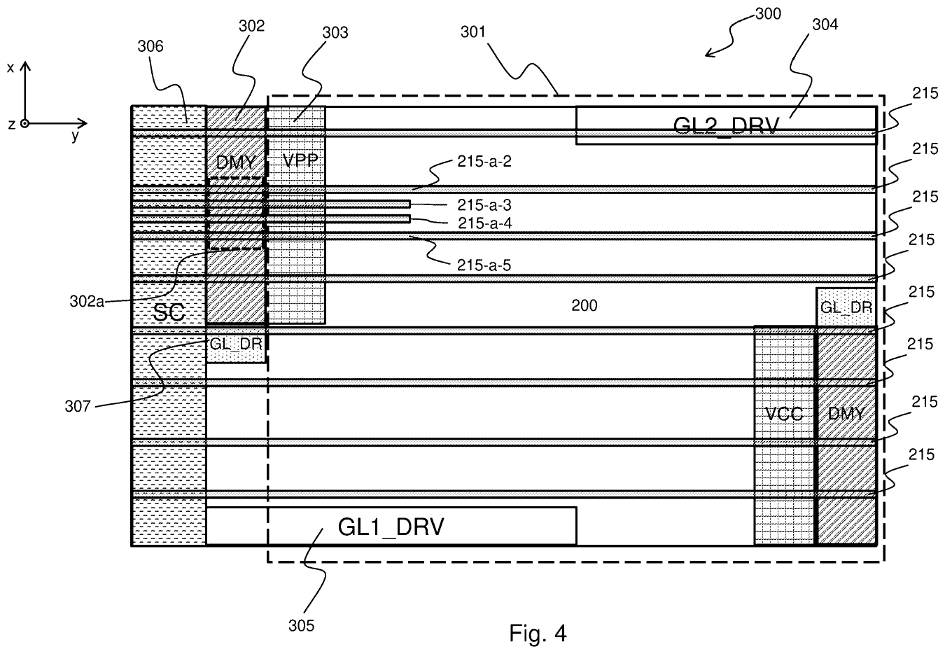

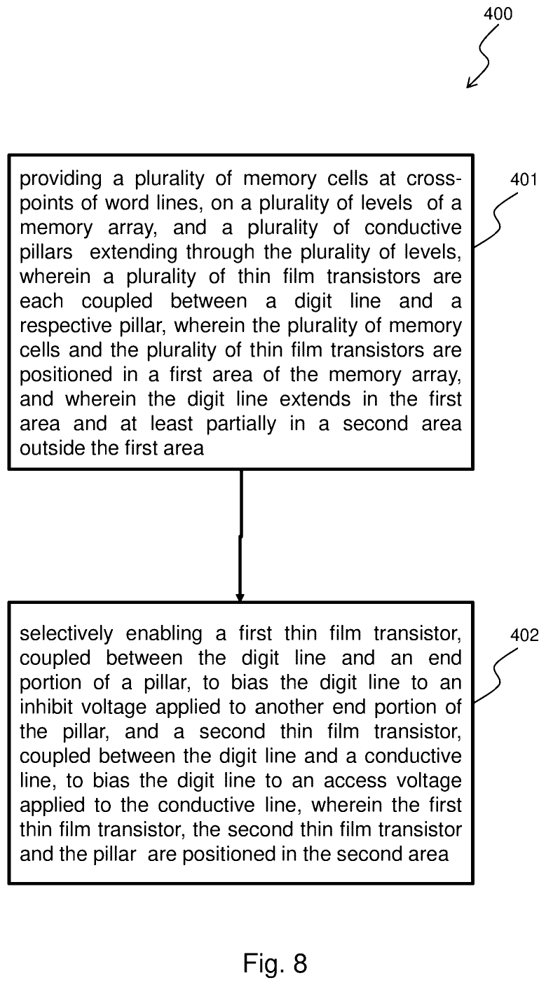

Features of the disclosure are initially described in the context of memory devices and arrays with reference to FIGS. 1, 2, 3A, and 3B. Features of the disclosure are described in the context of a portion of memory devices and digit line driver with reference to FIGS. 4-5, 6A-6C and 7A-7B and a driving method described with reference to FIG. 8.

FIG. 1 shows an example of a memory device 100 that supports driving of digit lines in a memory array in accordance with examples as disclosed herein. In some examples, the memory device 100 may be referred to as or include a memory die, a memory chip, or an electronic memory apparatus. The memory device 100 may be operable to provide physical memory locations (e.g., addresses) that may be used or referenced by a system (e.g., a host device coupled with the memory device 100).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (IN), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide glass may include additional elements such as hydrogen (H), oxygen (O), nitrogen (N), chlorine (CI), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting memory cell may have a high threshold voltage state and a low threshold voltage state. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

The devices discussed herein, including the memory cells 105, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The term “layer” or “level” or tier used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In some examples of the memory device 100, a memory cell 105 may be accessed (e.g., written to, read from) based on an electrical current through the memory cell 105. For example, a logic state may be written to a memory cell 105 based on a current driven through the memory cell 105 (e.g., an amount of current, a direction of current), and a logic state may be read from the memory cell 105 based on a current (e.g., a presence of current, an absence of current, an amount of current) through the memory cell 105 in response to a read bias across the memory cell 105. In some examples, memory cells 105 may be accessed based on various decoding architectures, which may implement transistors or other switching components (e.g., of a row decoder 110, of a column decoder 120) to access selected memory cells 105 in accordance with an addressing scheme. For example, for accessing certain memory cells 105, a voltage may be applied to gates of some transistors for coupling some conductive structures (e.g., for coupling access lines across a channel of the transistors), and the voltage may not be applied to gates of other transistors to maintain an isolation between other conductive structures.

For a given set of memory cells 105 (e.g., a section of memory cells, a tile of memory cells), a driver associated with driving access currents through the memory cells 105 may be associated with a relatively higher current than a driver associated with coupling conductive structures (e.g., a driver associated with biasing transistor gates, a driver associated with activating transistor channels, a driver associated with a row decoder, a driver associated with a column decoder) in accordance with an addressing scheme of the set of memory cells 105. In some examples, a driver associated with a relatively higher current may be associated with a relatively larger footprint of a memory die, or a relatively higher current density through interconnecting structures such as socket regions, among other differences compared with a driver associated with a relatively lower current.

In accordance with examples as disclosed herein, the column decoder 120 is implemented at least partially within a dummy area (also referred hereinafter as “second area”) which is separate with respect to the area (also referred as “first area”) including the set of active memory cells 105. The dummy area has a structure similar to that of the first area of the memory cells 105, with the difference that the memory cells of the dummy area are inactive during the operation of the memory device 100.

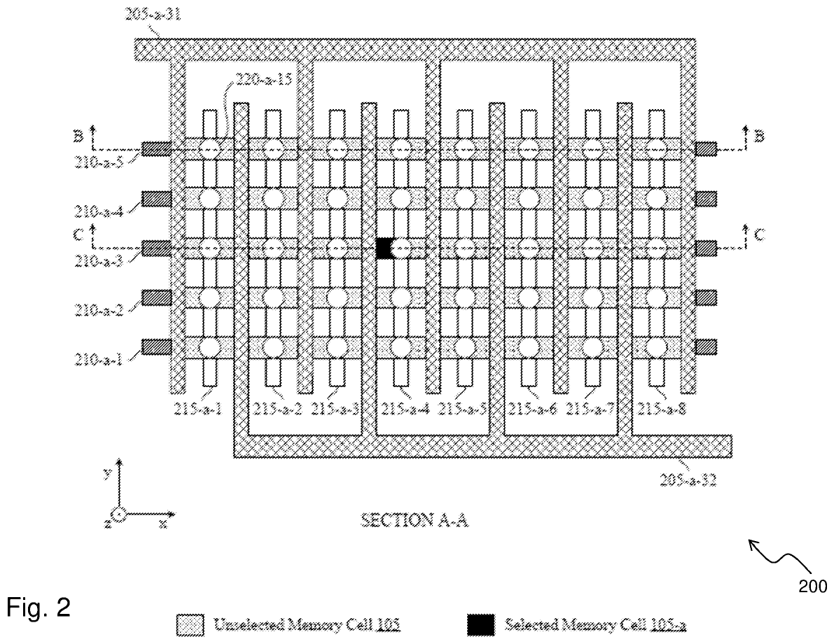

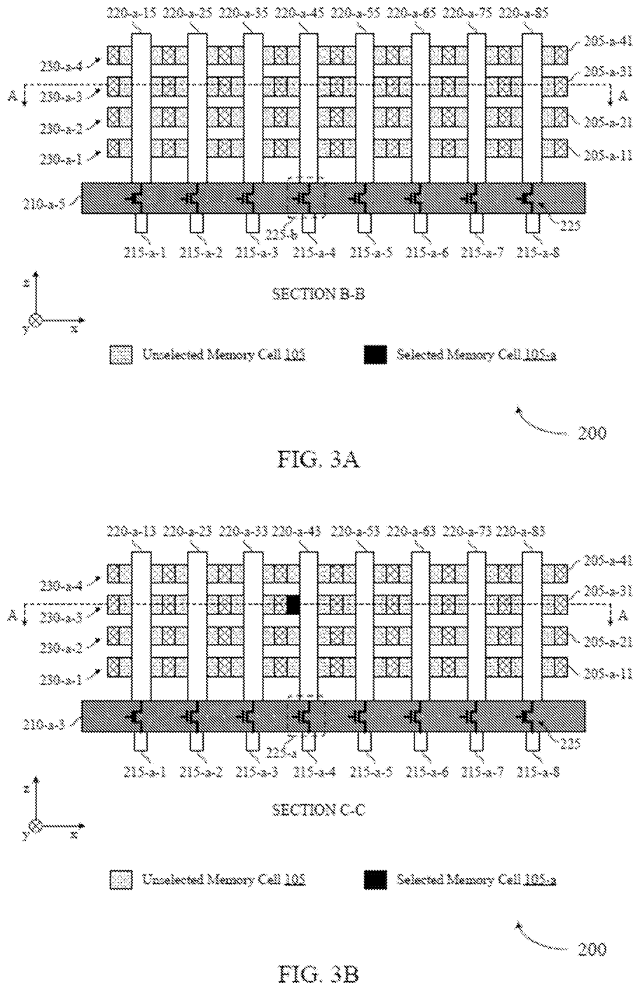

FIGS. 2, 3A, and 3B show an example of a memory array 200 that supports driving of digit lines in a memory array in accordance with examples as disclosed herein. The memory array 200 may be included in a memory device 100 and shows an example of a three dimensional arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers as illustrated in FIGS. 3A and 3B). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a digit line).

The transistors 225 may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path, along an end of the pillars 220 opposite from the transistors 225) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{read}/2, or some other negative bias or bias relatively near the access bias voltage), such that none of the transistors 225 along an unselected gate line 210 are activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

For a given set of memory cells 105 associated with the memory array 200 (e.g., a section of memory cells, a tile of memory cells), a driver associated with driving access currents through the memory cells 105 (e.g., a driver coupled with the word lines 205, a word line driver, a driver coupled with sense lines 215) may be associated with a relatively higher current than a driver associated with coupling conductive structures (e.g., a driver associated with activating transistors 225, a gate line driver) in accordance with an addressing scheme of the memory array 200. In some examples, a driver associated with a relatively higher current may be associated with a relatively larger footprint of the memory array 200 (e.g., along the x-direction, along the y-direction), or a relatively higher current density through interconnecting structures such as socket regions, among other differences compared with a driver associated with a relatively lower current.

In accordance with examples as disclosed herein, the column decoder 120 is implemented at least partially within a second dummy area which is separate with respect to the first area of the plurality of active memory cells 105.

For example, the active memory cells 105 are formed above the substrate of the first area, the word lines 205 are formed above the first area, and a first plurality of conductive pillars 220 and a first plurality of thin film transistors are formed above the first area. A second plurality of conductive dummy pillars, a second plurality of thin film transistors and a second plurality of gate lines are formed inside the second dummy area. At least part of the digit lines 215 extends at least partially across the second dummy area. A digit line driver is provided for driving the at least part of the digit lines 215 extending in the dummy area in order to access the memory cells 105. The digit line driver comprises at least a portion of the second plurality of dummy pillars and at least a portion of the second plurality of thin film transistors.

In some examples, each of the thin film transistors of said portion of the second plurality of thin film transistors comprises a conductive channel interposed between an end portion of a dummy pillar of the at least portion of the second plurality of dummy pillars and a digit line extending in the dummy area. At least part of the second plurality of thin film transistors are arranged in a plurality of groups. Each group comprises a first thin film transistor with a first channel for electrically coupling a portion of a digit line extending in the dummy area to an end portion of a first pillar of the at least portion of the second plurality of dummy pillars, said first pillar having another end portion biased to an inhibit voltage, wherein the first thin film transistor comprises a first gate terminal configured to be biased to an activation voltage for enabling the bias of the digit line to the inhibit voltage. Each group of the at least part of the second plurality of thin film transistors further comprises a second thin film transistor with a second channel for biasing the portion of said digit line to an access voltage, wherein the second thin film transistor comprises a second gate terminal configured to carry a voltage value for enabling the bias of the digit line to the access voltage.

By implementing the digit line driver in accordance with examples as disclosed therein, a memory device 100 may be implemented with increased area available under the 3D array of memory cells 105 for placing circuitry for operating the memory device 100, increased driving capability of the digit lines 215 which allows to activate simultaneously a plurality of memory cells and reduced routing congestion of digit lines 215, among other benefits.

FIG. 4 shows an example of a layout 300 including the digit line driver in accordance with examples as disclosed therein. The layout 300 may be an example of a block diagram implementing aspects of the memory device 100 described with reference to FIG. 1 and aspects of the memory array 200 described with reference to FIGS. 2, 3A and 3B.

The layout 300 includes a first area 301 comprising the memory array 200 formed in the substrate and includes a plurality of digit lines 215, some of which are examples of the sense lines 215-a-2, 215-a-3, 215-a-4, 215-a-5 described with reference to FIG. 2. For the sake of illustrative clarity FIG. 4 shows only a part of the digit lines of FIG. 2. The first area 301 further includes various arrangements of a first plurality of pillars 220 (e.g., a two-dimensional array of pillars 220), memory cells 105 (e.g., a three-dimensional array of active memory cells 105), and a first plurality of transistors 225 (e.g., a two-dimensional array of transistors 225), which also may be examples of the respective components described with reference to FIGS. 2, 3A, and 3B, though such components are omitted from FIG. 4 for the sake of illustrative clarity. The first area 301 further includes at least portions of two gate line drivers 304 and 305 for driving the gate lines 210-a-1, 210-a-2, 210-a-3, 210-a-4, 210-a-5 described with reference to FIG. 2; in particular, gate line drivers 304 and 305 are configured to generate a positive or negative supply voltage (for example, equal to 5 Volt, 2 Volt, −3.5 Volt) or a ground reference voltage (0 Volt). The first area 301 further includes a supply voltage generator 303 for generating an access voltage VPP (for example equal to 3.5 Volt or −3.5 Volt). The supply voltage generator 303 may also be referred to as digit line pre-decoder. Aspects of the layout 300 may be described with reference to an x-direction (e.g., a row direction), a y-direction (e.g., a column direction), and a z-direction (e.g., a level direction).

The layout 300 further includes a second area 302 (previously referred as “dummy” area) comprising inactive memory cells. The digit lines 215 extend at least partially across the second area 302. The second area 302 has a structure similar to that of the first area 301, i.e. various arrangements of the second plurality of dummy pillars (e.g., a two-dimensional array of the second plurality of dummy pillars), a second plurality of transistors (e.g., a two-dimensional array of thin film transistors), a second plurality of gate lines (e.g. a plurality of gate lines parallel each other and extending over a direction substantially perpendicular to the direction of the digit lines) and memory cells, with the difference that the memory cells of the second area 302 are inactive during the operation of the memory device 100.

In one example, the second area 302 includes one or more portions 302a (only one of which is depicted in FIG. 4) of the digit line driver for selectively driving a corresponding portion of the plurality of digit lines (e.g., digit lines 215-a-2, 215-a-3, 215-a-4, 215-a-5 in the depicted example of FIG. 4) extending in the second area 302, in particular for selectively biasing the digit lines 215 to the access voltage VPP (for example, equal to 3.5 Volt or −3.5 Volt) or to an inhibit voltage VSS (for example, a ground voltage or floating). The plurality of digit lines in each tile is organized in groups and each group is associated to a respective digit line driver portion 302a. Each digit line driver portion 302a receives the corresponding access voltage VPP from the voltage supply generator 303 and receives the activation voltage or deactivation voltage from a gate line biasing circuit 307.

More in detail, the second area 302 includes the second plurality of conductive dummy pillars, which may be arranged in a two-dimensional array (e.g., in an xy-plane) having a first quantity of dummy pillars along a first direction (e.g., eight dummy pillars along the x-direction, eight rows of dummy pillars) and having a second quantity of dummy pillars along a second direction (e.g., four rows of dummy pillars along the y-direction, four columns of dummy pillars). Each of the dummy pillars of the second plurality has a cross-sectional area in an xy-plane that extends along the z-direction. Although illustrated with a circular cross-sectional area in the xy-plane, each of the dummy pillars of the second plurality may be formed with a different shape, such as having an elliptical, square, rectangular, polygonal, or other cross-sectional area in an xy-plane. At least some of the dummy pillars of the second plurality has one end coupled to one end of a conductive channel of a thin film transistor of the second plurality of thin film transistors, as it will be described in more detail below. At least some of the dummy pillars of the second plurality has the other end which may be biased to the inhibit voltage (for example, ground reference voltage) or it may be floating.

The second area 302 further includes the second plurality of thin film transistors formed above the substrate. Each of the thin film transistors of the second plurality of thin film transistors has a conductive channel having one end coupled to a portion of a respective digit line 215-a-2, 215-a-3, 215-a-4, 215-a-5 extending in the second area 302, and having another end which may be coupled to one end of a dummy pillar of the second plurality of dummy pillars and/or it may be biased to the access voltage VPP.

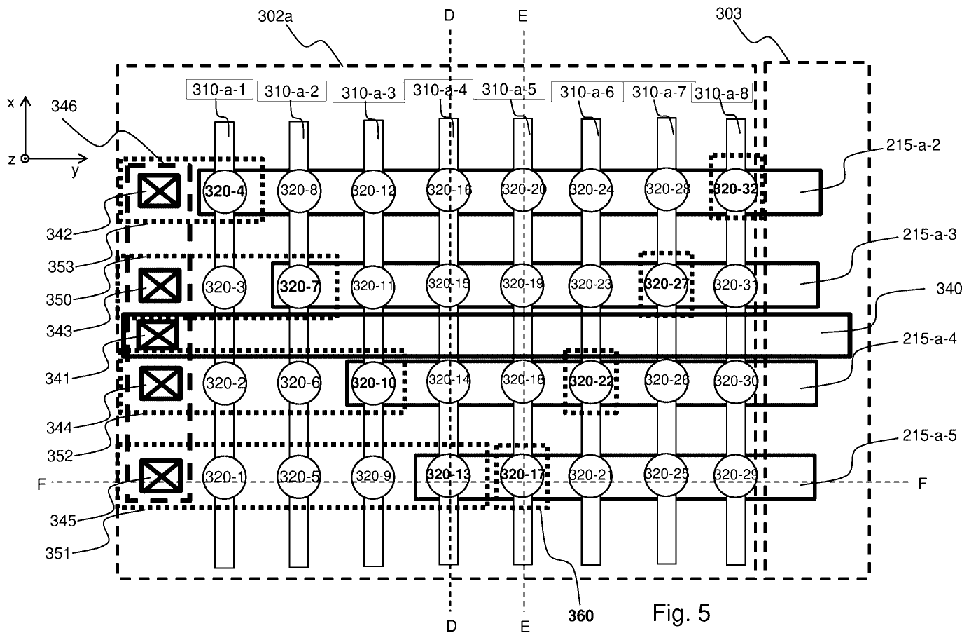

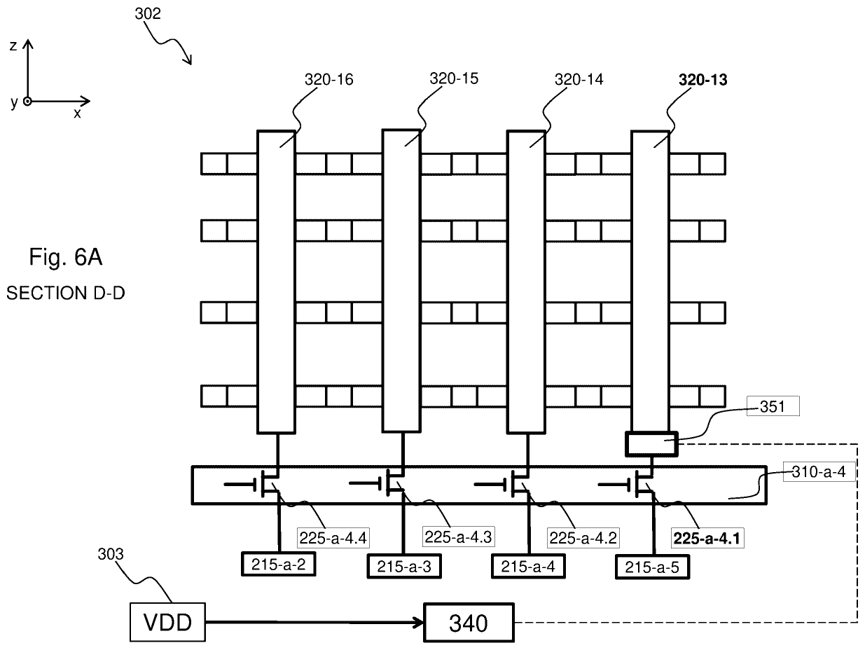

The second area 302 further includes a second plurality of gate lines (see 310-a-1, 310-a-2, 310-a-3, 310-a-4, 310-a-5, 310-a-6, 310-a-7, 310-a-8 in FIG. 5), wherein each of the gate line of the second plurality is coupled with respective gates of a subset of thin film transistors of the second plurality of thin film transistors.

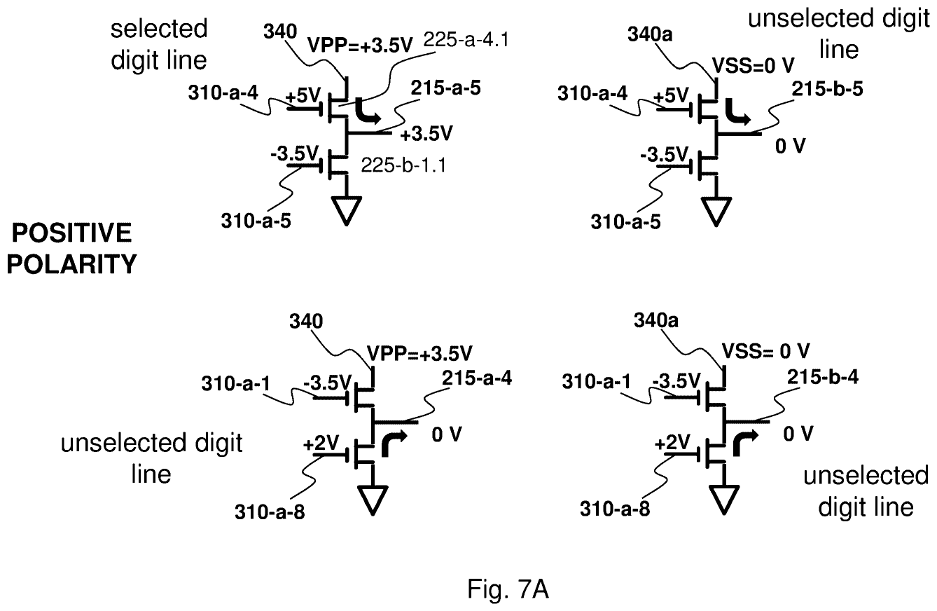

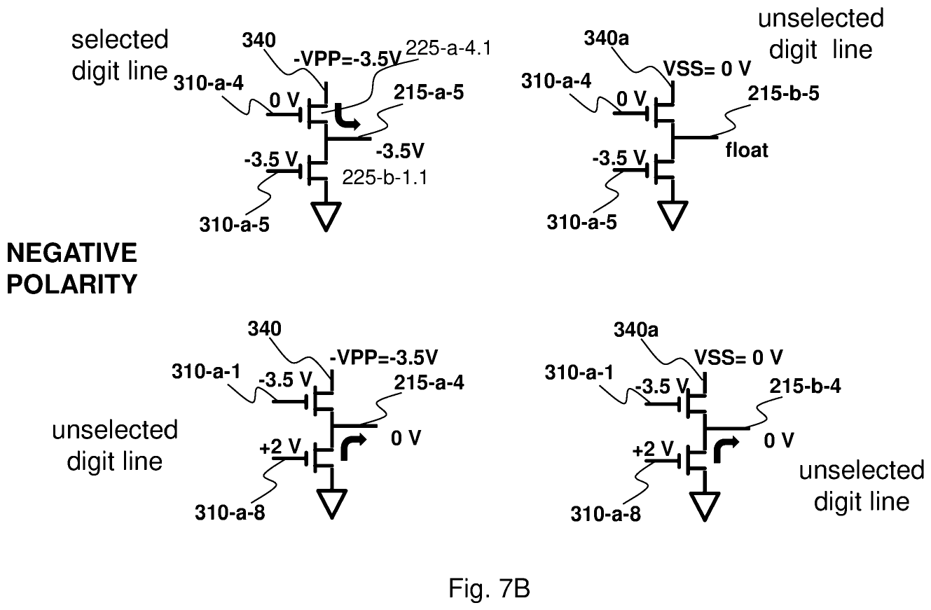

The layout 300 further includes a gate line biasing circuit 307 for driving the second plurality of gate lines, wherein the gate line biasing circuit 307 is positioned inside the second area 302. In particular, the gate line biasing circuit 307 is configured to generate an activation voltage which is a positive or negative supply voltage (for example, equal to 5 Volt, 2 Volt or −3.5 Volt) or a ground reference voltage (0 Volt) for setting the voltage value of the second plurality of gate lines, as explained below with reference to FIG. 7A-7B, in order to selectively activate at least a portion of the second plurality of thin film transistors.

The layout 300 further includes an area 306 including elements to access the vertically stacked word lines, in particular a staircase, wherein each step of the staircase corresponds to a respective level of the 3D vertical memory array.

FIG. 5 shows more in detail a top view of the digit line driver portion 302a comprising a part of the first area 302 and comprising the voltage supply generator 303 of the second area 301 of FIG. 4.

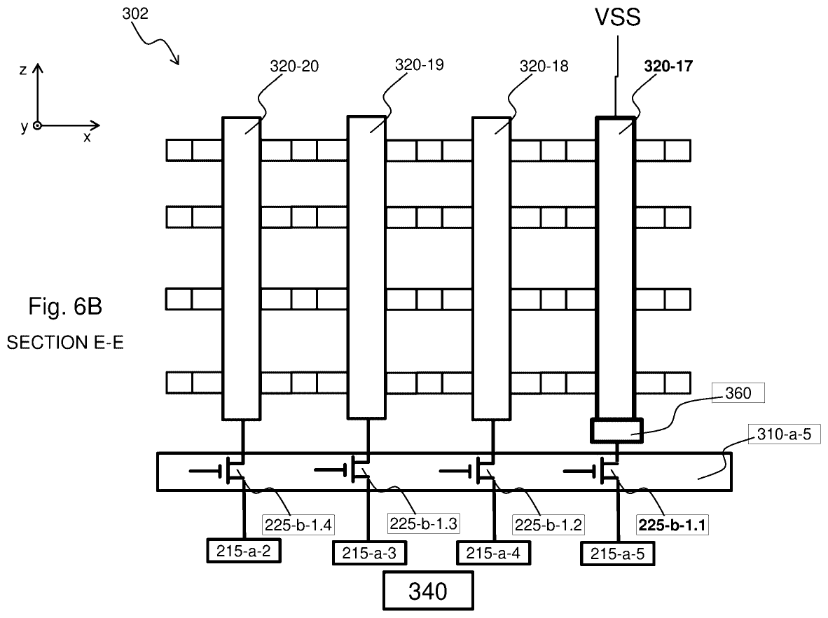

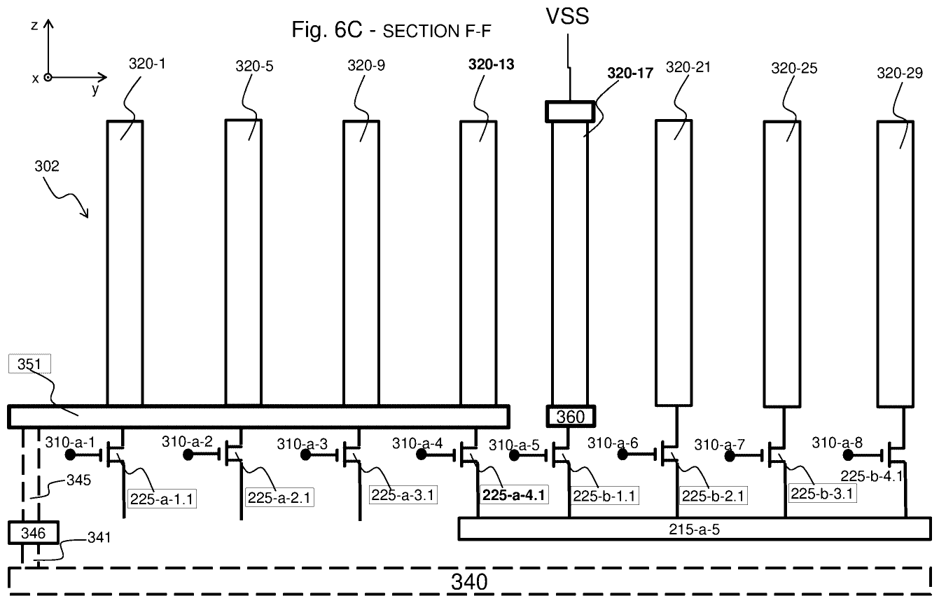

In order to understand FIG. 5, reference to FIGS. 6A, 6B, 6C may also be useful, wherein FIG. 6A shows a side section view of the second area 302 relative to a cut plane D-D of FIG. 5, FIG. 6B shows a side section view of the second area 302 relative to a cut plane E-E of FIG. 5 and FIG. 6C shows a side section view of the second area 302 relative to a cut plane F-F of FIG. 5.

Digit line driver portion 302a implements part of the digit line driver described with reference to FIG. 4, in particular for selectively biasing the digit lines 215-a-2, 215-a-3, 215-a-4, 215-a-5 to the inhibit voltage VSS (for example, a ground voltage equal to 0 Volt) or to the access voltage VPP (for example, equal to +3.5 Volt or −3.5 Volt).

Digit line driver portion 302a further includes 32 dummy pillars 320-1, 320-2, . . . , 320-31, 320-32 selected from the second plurality of dummy pillars in the second area 302, wherein the 32 dummy pillars 320-1, 320-2, . . . 320-31, 320-32 are arranged in a two-dimensional array.

In particular, the array of dummy pillars includes a first column composed of four dummy pillars 320-1, 320-2, 320-3, 320-4, a second column composed of four dummy pillars 320-5, 320-6, 320-7, 320-8, a third column composed of four dummy pillars 320-9, 320-10, 320-11, 320-12, a fourth column composed of four dummy pillars 320-13, 320-14, 320-15, 320-16, a fifth column composed of four dummy pillars 320-17, 320-18, 320-19, 320-20, a sixth column composed of four dummy pillars 320-21, 320-22, 320-23, 320-24, a seventh column composed of four dummy pillars 320-25, 320-26, 320-27, 320-28, and an eigth column composed of four dummy pillars 320-29, 320-30, 320-31, 320-32. The example of 32 dummy pillars depicted in FIG. 5 is only for illustrative purposes. Other arrangements of dummy pillars may be considered, comprising a different number of rows and/or columns.

Digit line driver portion 302a further includes 32 vertical thin film transistors (not shown) of the second plurality of thin film transistors, wherein the 32 vertical thin film transistors of the second plurality are arranged in a two-dimensional array with same dimensions as the two-dimensional array of the dummy pillars. Each of the thin film transistors of the second plurality has a respective channel interposed between a respective digit line selected from digit lines 215-a-2, 215-a-3, 215-a-4, 215-a-5 and a respective dummy pillar selected from the dummy pillars 320-1, 320-2, . . . 320-32.

In particular:
a first column is composed of four thin film transistors having respective channel interposed between a corresponding digit line out of 215-a-2, 215-a-3, 215-a-4, 215-a-5 and a respective dummy pillar out of 320-1, 320-2, 320-3, 320-4;
a second column is composed of four thin film transistors having respective channel interposed between a corresponding digit line out of 215-a-2, 215-a-3, 215-a-4, 215-a-5 and a respective dummy pillar out of 320-5, 320-6, 320-7, 320-8;
. . . ;
an eight column is composed of four thin film transistors having respective channel interposed between a corresponding digit line out of 215-a-2, 215-a-3, 215-a-4, 215-a-5 and a respective dummy pillar out of 320-29, 320-30, 320-31, 320-32.

Digit line driver portion 302a further includes 8 gate lines 310-a-1, 310-a-2, 310-a-3, 310-a-4, 310-a-5, 310-a-6, 310-a-7, 310-a-8, wherein each gate line is electrically connected to the gate terminals of four thin film transistors of a column of the array of thin film transistors.

More in detail:
gate line 310-a-1 is connected to the gate terminals of four thin film transistors arranged under four respective dummy pillars 320-1, 320-2, 320-3, 320-4;
gate line 310-a-2 is connected to the gate terminals of four thin film transistors arranged under four respective dummy pillars 320-5, 320-6, 320-7, 320-8;
gate line 310-a-3 is connected to the gate terminals of four thin film transistors arranged under four respective dummy pillars 320-9, 320-10, 320-11, 320-12;
gate line 310-a-4 is connected to the gate terminals of four thin film transistors arranged under four respective dummy pillars 320-13, 320-14, 320-15, 320-16;
gate line 310-a-5 is connected to the gate terminals of four thin film transistors arranged under four respective dummy pillars 320-17, 320-18, 320-19, 320-20;
gate line 310-a-6 is connected to the gate terminals of four thin film transistors arranged under four respective dummy pillars 320-21, 320-22, 320-23, 320-24;
gate line 310-a-7 is connected to the gate terminals of four thin film transistors arranged under four respective dummy pillars 320-25, 320-26, 320-27, 320-28;
gate line 310-a-8 is connected to the gate terminals of four thin film transistors arranged under four respective dummy pillars 320-29, 320-30, 320-31, 320-32.

In one embodiment, at least part of the dummy pillars 320-1, 320-2, . . . 320-32 and the corresponding thin film transistors arranged below the dummy pillars 320-1, 320-2, . . . 320-32 are arranged into four groups, wherein each group has the function to set the voltage value of a digit line out of the digit lines 215-a-2, 215-a-3, 215-a-4, 215-a-5.

In particular:
a first group is composed of dummy pillar 320-32, thin film transistor arranged under dummy pillar 320-32 and thin film transistor arranged under dummy pillar 320-4;
a second group is composed of dummy pillar 320-27, thin film transistor arranged under dummy pillar 320-27 and thin film transistor arranged under dummy pillar 320-7;
a third group is composed of dummy pillar 320-22, thin film transistor arranged under dummy pillar 320-22 and thin film transistor arranged under dummy pillar 320-10;
a fourth group is composed of dummy pillar 320-17, thin film transistor arranged under dummy pillar 320-17 and thin film transistor arranged under dummy pillar 320-13.

The first group has the function to set the voltage value of the digit line 215-a-2, depending on the voltage value of the gate lines 310-a-8 and 310-a-1, wherein when one gate line out of 310-a-8 and 310-a-1 is set to an activation voltage, the other gate line out of 310-a-8 and 310-a-1 is set to a deactivation voltage. In particular, when gate line 310-a-8 is set to the activation voltage and gate line 310-a-1 is set to the deactivation voltage, dummy pillar 320-32 is set to an access voltage, dummy pillar 320-4 is floating and dummy pillars 320-8, 320-12, 320-16, 320-20, 320-24, 320-28 (and corresponding thin film transistor arranged under dummy pillars 320-8, 320-12, 320-16, 320-20, 320-24, 320-28) are not relevant for the biasing of the digit line 215-a-2. Viceversa, when gate line 310-a-8 is set to the deactivation voltage and gate line 310-a-1 is set to the activation voltage, dummy pillar 320-32 is floating, dummy pillar 320-4 is set to the access voltage and dummy pillars 320-8, 320-12, 320-16, 320-20, 320-24, 320-28 (and corresponding thin film transistor arranged under dummy pillars 320-8, 320-12, 320-16, 320-20, 320-24, 320-28) are not relevant for the biasing of the digit line 215-a-2.

The second group has the function to set the voltage value of the digit line 215-a-3, depending on the voltage value of the gate lines 310-a-7 and 310-a-2, wherein when one gate line out of 310-a-7 and 310-a-2 is set to the activation voltage, the other gate line out of 310-a-7 and 310-a-2 is set to the deactivation voltage. In particular, when gate line 310-a-7 is set to the activation voltage and gate line 310-a-2 is set to the deactivation voltage, dummy pillar 320-27 is set to the access voltage, dummy pillar 320-7 is floating and dummy pillars 320-3, 320-11, 320-15, 320-19, 320-23, 320-31 (and corresponding thin film transistor arranged under dummy pillars 320-3, 320-11, 320-15, 320-19, 320-23, 320-31) are not relevant for the biasing of the digit line 215-a-3. Viceversa, when gate line 310-a-7 is set to the deactivation voltage and gate line 310-a-2 is set to the activation voltage, dummy pillar 320-27 is floating, dummy pillar 320-7 is set to the access voltage and dummy pillars 320-3, 320-11, 320-15, 320-19, 320-23, 320-31 (and corresponding thin film transistor arranged under dummy pillars 320-3, 320-11, 320-15, 320-19, 320-23, 320-31) are not relevant for the biasing of the digit line 215-a-3.

The third group has the function to set the voltage value of the digit line 215-a-4, depending on the voltage value of the gate lines 310-a-6 and 310-a-3, wherein when one gate line out of 310-a-6 and 310-a-3 is set to the activation voltage, the other gate line out of 310-a-6 and 310-a-3 is set to the deactivation voltage. In particular, when gate line 310-a-6 is set to the activation voltage and gate line 310-a-3 is set to the deactivation voltage, dummy pillar 320-22 is set to the access voltage, dummy pillar 320-10 is floating and dummy pillars 320-2, 320-6, 320-14, 320-18, 320-26, 320-30 (and corresponding thin film transistor arranged under dummy pillars 320-2, 320-6, 320-14, 320-18, 320-26, 320-30) are not relevant for the biasing of the digit line 215-a-4. Viceversa, when gate line 310-a-6 is set to the deactivation voltage and gate line 310-a-3 is set to the activation voltage, dummy pillar 320-22 is floating, dummy pillar 320-10 is set to the access voltage and dummy pillars 320-2, 320-6, 320-14, 320-18, 320-26, 320-30 (and corresponding thin film transistor arranged under dummy pillars 320-2, 320-6, 320-14, 320-18, 320-26, 320-30) are not relevant for the biasing of the digit line 215-a-4.

The fourth group has the function to set the voltage value of the digit line 215-a-5, depending on the voltage value of the gate lines 310-a-5 and 310-a-4, wherein when one gate line out of 310-a-5 and 310-a-4 is set to the activation voltage, the other gate line out of 310-a-5 and 310-a-is set to the deactivation voltage. In particular, when gate line 310-a-5 is set to the activation voltage and gate line 310-a-4 is set to the deactivation voltage, dummy pillar 320-17 is set to the access voltage, dummy pillar 320-13 is floating and dummy pillars 320-1, 320-5, 320-9, 320-21, 320-25, 320-29 (and corresponding thin film transistor arranged under dummy pillars 320-1, 320-5, 320-9, 320-21, 320-25, 320-29) are not relevant for the biasing of the digit line 215-a-5. Viceversa, when gate line 310-a-5 is set to the deactivation voltage and gate line 310-a-4 is set to the activation voltage, dummy pillar 320-17 is floating, dummy pillar 320-13 is set to the access voltage and dummy pillars 320-1, 320-5, 320-9, 320-21, 320-25, 320-29 (and corresponding thin film transistor arranged under dummy pillars 320-1, 320-5, 320-9, 320-21, 320-25, 320-29) are not relevant for the biasing of the digit line 215-a-5.

The electrical connections of the thin film transistors and dummy pillars of the fourth group will be described in detail below with reference to FIGS. 6A, 6B, 6C, 7A and 7B.

The digit line driver portion 302a includes a conductive line 340 extending along the y-direction, a conductive line 346 extending along the x-direction, four conductive lines 350, 351, 352, 353 extending along the y-direction and a conductive element 360, wherein (see FIG. 6C) the conductive line 340 is arranged in the lowest level along the z-direction, the conductive lines 350, 351, 352, 353 and the conductive element 360 are arranged in the highest level along the z-direction and the conductive line 346 is arranged in an intermediate level along the z-direction (i.e. comprised between the level of conductive line 340 and the level of the conductive lines 350, 351, 352, 353, for example at the same level of digit lines 215). A conductive via 341 is formed for electrically connecting the conductive line 340 to the conductive line 346, a conductive via 342 for electrically connecting the conductive line 346 to the conductive line 353, a conductive via 343 for electrically connecting the conductive line 346 to the conductive line 350, a conductive via 344 for electrically connecting the conductive line 346 to the conductive line 352, and a conductive via 345 for electrically connecting the conductive line 346 to the conductive line 351. The conductive line 340 is electrically connected to the voltage supply generator 303, so that the voltage value of conductive line 340 is set to the access voltage VPP (for example, equal to +3.5 Volt or −3.5 Volt) or is set to a ground voltage (0 Volt).

It is described hereinafter a first example of a digit line driver for setting a voltage value to digit line 215-a-5 to the inhibit voltage VSS (in particular, a ground voltage) or, alternatively, to the access voltage VPP (in particular, equal to +3.5 Volt), provided that a suitable activation voltage is set to the gate lines 310-a-4 and 310-a-5.

The electrical path comprising the conductive line 340, conductive via 341, conductive line 346, conductive via 345, conductive line 351, thin film transistor 225-a-4.1 under dummy pillar 320-13 (driven by gate line 310-a-4) implements a portion (or a branch) of the digit line driver for driving the digit line 215-a-5 extending in the second area 302. In particular, the conductive line 340 is coupled at one end portion to the access voltage (for example equal to +3.5 Volt), which is generated by the voltage supply generator 303. The other end portion of the conductive line 340 is electrically connected to the conductive line 346 by means of via 341, the conductive line 346 is connected to the conductive line 351 by means of via 345, the conductive line 351 is connected to one end of the channel of the thin film transistor arranged under dummy pillar 320-13, while the other end of the channel of the thin film transistor 225-a-4.1 (arranged under dummy pillar 320-13) is connected to a portion of the digit line 215-a-5 extending in the second area 302: in this way the digit line 215-a-5 may be set to the access voltage (in particular, equal to +3.5 Volt) during operation of the memory device 100, provided that a suitable activation voltage is set to the gate line 310-a-4. Thin film transistor 225-a-4.1 is also referred as “pull-up transistor”, because it has the function to bias the digit line 215-a-5 to the access voltage VPP (for example equal to +3.5 Volt). Each of the thin film transistors 225-a-1.1, 225-a-2.1, 225-a-3.1 (arranged under dummy pillars 320-1, 320-5, 320-9, respectively) has one end of the conductive channel biased to the access voltage (in particular, a supply voltage equal to +3.5 Volt), by means of the conductive line 351, via 345, conductive line 346, via 341 and conductive line 340, while the other end of the channel of each of the thin film transistors arranged under dummy pillars 320-1, 320-5, 320-9 is floating, e.g., it is not connected to the digit line 215-a-5 because (as illustrated in FIG. 5) digit line 215-a-5 extends (from the active portion of the array on the right) only to dummy pillar 320-13. In any case, during an access operation to digit line 215-a-5, such thin film transistors 225-a-1.1, 225-a-2.1, 225-a-3.1 (arranged under dummy pillars 320-1, 320-5, 320-9, respectively) have respective gate lines 310-a-1, 310-a-2 and 310-a-3 biased to a deactivation voltage (for example equal to −3.5 Volt). In other words, the access voltage is transferred to digit line 215-a-5 activating thin film transistor 225-a-4.1 under dummy pillar 320-13 by setting the gate line 310-a-4 to the activation voltage (for example equal to +5 Volt), deactivating thin film transistor 225-b-1.1 under dummy pillar 320-17 by biasing the gate line 310-a-5 to the deactivation voltage (for example equal to −3.5 Volt), and the other thin film transistors 225-a-1.1, 225-a-2.1, 225-a-3.1 in the same column of digit line 215-a-5 being deactivated (i.e. switched off) by biasing the gate lines 310-a-1, 310-a-2, 310-a-3 to the deactivation voltage (for example equal to −3.5 Volt) and/or being irrelevant because not coupled to the digit line 215-a-5.

The electrical path comprising the dummy pillar 320-17, conductive element 360, thin film transistor 225-b-1.1 under the dummy pillar 320-17 (driven by gate line 310-a-5) implements another portion (or branch) of the digit line driver for driving the portion of the digit line 215-a-5 extending in the second area 302. In particular, dummy pillar 320-17 has one end portion connected to an inhibit voltage VSS (for example, a ground reference voltage) and another end portion connected to one end of the conductive channel of the thin film transistor under dummy pillar 320-17 by means of the conductive contact 360, while the other end of the conductive channel of the thin film transistor under dummy pillar 320-17 is connected to the digit line 215-a-5 extending in the second area 302: in this way the digit line 215-a-5 may be set to the inhibit voltage VSS during operation of the memory device 100, provided that a suitable activation voltage is set to the gate line 310-a-5 (for example, 2 Volts). Thin film transistor 225-b-1.1 is also referred as “pull-down transistor”, because it has the function to bias the digit line 215-a-5 to the inhibit voltage VSS (for example equal to 0 Volt).

Dummy pillars 320-21, 320-25 and 320-29 are floating, so that they are not relevant for the biasing of the digit line 215-a-5.

Referring again to FIG. 6C and also to the driving circuit on top-left of FIG. 7A, when selecting the digit line 215-a-5, one end of the channel of thin film transistor 225-a-4.1 (arranged under dummy pillar 320-13) is connected to the access voltage VPP (for example equal +3.5 Volt) generated by the supply voltage generator 303, while the other end of the channel of thin film transistor 225-a-4.1 is connected to the digit line 215-a-5. Dummy pillar 320-13 has one end portion connected to thin film transistor 225-a-4.1, while the other end portion is floating, so that dummy pillar 320-13 is not relevant for the biasing of the digit line 215-a-5. Dummy pillars 320-1, 320-5, 320.9 are also not relevant for the biasing of the digit line 215-a-5, because corresponding thin film transistors 225-a-1.1, 225-a-2.1, 225-a-3.1 have one end portion which is floating. An activation voltage (for example equal to +5 Volt) is set to the gate line 310-a-4, so that thin film transistor 225-a-4.1 is activated (i.e. conducting state). A deactivation voltage (for example equal to −3.5 Volt or 0 Volt) is set to the gate line 310-a-5, so that thin film transistor 225-b-1.1 (arranged under dummy pillar 320-17) is deactivated (i.e. non conducting state). In this way the digit line 215-a-5 is driven only to the access voltage VPP (for example equal to 3.5 Volt) generated by the supply voltage generator 303.

When unselecting the digit line 215-a-5, a deactivation voltage (for example, equal to −3.5 Volt or 0 Volt) is set to the gate line 310-a-4, so that thin film transistor 225-a-4.1 is deactivated (i.e. non conducting state). At the same time, an activation voltage (for example, equal to 2 Volt) is set to the gate line 310-a-5 and the inhibit voltage VSS (for example equal to 0 Volt) is set to the dummy pillar 320-17, so that thin film transistor 225-b-1.1 (arranged under dummy pillar 320-17) is activated (i.e. conducting state). In this way the digit line 215-a-5 is driven only to the inhibit voltage VSS (for example equal to 0 Volt) generated by a source of the inhibit voltage VSS.

It is described hereinafter a second example of the digit line driver for setting a voltage value to digit line 215-a-2 to the inhibit voltage VSS (in particular, a ground voltage) or, alternatively, to the access voltage VPP (in particular, equal to +3.5 Volt), provided that a suitable activation voltage is set to the gate lines 310-a-1 and 310-a-8.

The electrical path comprising the conductive line 340, conductive via 341, conductive line 346, conductive via 342, conductive line 353, thin film transistor under dummy pillar 320-4 (driven by gate line 310-a-1) implements a portion (or a branch) of the digit line driver for driving the portion of the digit line 215-a-2 extending in the second area 302. In particular, the conductive line 340 is biased at one end portion to a access voltage (for example equal to 3.5+Volt), which is generated by the voltage supply generator 303. The other end portion of the conductive line 340 is electrically connected to the conductive line 346 by means of via 341, the conductive line 346 is connected to the conductive line 353 by means of via 342, the conductive line 353 is connected to one end of the channel of the thin film transistor arranged under dummy pillar 320-4, while the other end of the channel of the thin film transistor arranged under dummy pillar 320-4 is connected to a portion of the digit line 215-a-2 extending in the second area 302: in this way the digit line 215-a-2 may be set to the access voltage (in particular, equal to +3.5 Volt) during operation of the memory device 100, provided that a suitable activation voltage is set to the gate line 310-a-1.

The electrical path comprising the dummy pillar 320-32, thin film transistor under the dummy pillar 320-32 (driven by gate line 310-a-8) implements another portion (or branch) of the digit line driver for driving the portion of the digit line 215-a-2 extending in the second area 302. In particular, dummy pillar 320-32 has one end portion connected to an inhibit voltage VSS (for example, a ground reference voltage) and another end portion connected to one end of the conductive channel of the thin film transistor under dummy pillar 320-32, while the other end of the conductive channel of the thin film transistor under dummy pillar 320-32 is connected to the digit line 215-a-2 extending in the second area 302: in this way the digit line 215-a-2 may be set to the inhibit voltage-during operation of the memory device 100, provided that a suitable activation voltage is set to the gate line 310-a-8 (for example, 2 Volts).

Dummy pillars 320-8, 320-12, 320-16, 320-20, 320-24 and 320-28 are floating, so that they are not relevant for the biasing of the digit line 215-a-2.

In a third example of the digit line driver for setting a voltage value to the digit line 215-a-3, one portion (or branch) of the digit line driver includes the electrical path comprising the conductive line 340, conductive via 341, conductive line 346, via 343, conductive line 350, thin film transistor under dummy pillar 320-7 (driven by gate line 310-a-2): in this case the digit line 215-a-3 may be set to the access voltage during operation of the memory device 100, provided that a suitable activation voltage is set to the gate line 310-a-2 (for example, 2 Volts). Moreover, another portion (or branch) of the digit line driver includes the electrical path comprising the dummy pillar 320-27, thin film transistor under the dummy pillar 320-27 (driven by gate line 310-a-7): in this case the digit line 215-a-3 may be set to the inhibit voltage during operation of the memory device 100, provided that a suitable activation voltage is set to the gate line 310-b3 (for example, 2 Volts).

In a fourth example of the digit line driver for setting a voltage value to the digit line 215-a-4, one portion (or branch) of the digit line driver includes the electrical path comprising the conductive line 340, via 341, conductive line 346, via 344, conductive line 352, thin film transistor under dummy pillar 320-10 (driven by gate line 310-a-3): in this case the digit line 215-a-4 may be set to the access voltage during operation of the memory device 100, provided that a suitable activation voltage is set to the gate line 310-a-3. Moreover, another portion (or branch) of the digit line driver includes the electrical path comprising the dummy pillar 320-22, thin film transistor under the dummy pillar 320-22 (driven by gate line 310-a-6): in this case the digit line 215-a-4 may be set to the inhibit voltage during operation of the memory device 100, provided that a suitable activation voltage is set to the gate line 310-b2 (for example 2 Volts).

FIG. 6A shows a side section view of the second area 302 relative to a cut plane D-D as shown in FIG. 5, wherein some elements are removed for clarity.

In particular, FIG. 6A shows more in detail the structure of the fourth group of the digit line driver for setting the digit line 215-a-5 extending in the second area 302 to the access voltage (for example, equal to +3.5 Volt).

Thin film transistors 225-a-4.1, 225-a-4.2, 225-a-4.3, 225-a-4.4 are examples of thin film transistors of the second plurality of film thin transistors arranged in the second area 302 of the memory device 200 and dummy pillars 320-13, 320-14, 320-15, 320-16 are examples of dummy pillars of the second plurality of dummy pillars arranged in the second area 302 of the memory device 200.

Thin film transistor 225-a-4.1 is interposed between dummy pillar 320-13 and digit line 215-a-5, thin film transistor 225-a-4.2 is interposed between dummy pillar 320-14 and digit line 215-a-4, thin film transistor 225-a-4.3 is interposed between dummy pillar 320-15 and digit line 215-a-3 and thin film transistor 225-a-4.4 is interposed between dummy pillar 320-16 and digit line 215-a-2. More in detail, thin film transistor 225-a-4.1 is electrically connected to dummy pillar 320-13, while dummy pillars 320-14, 320-15, 320-16 are floating so that they are not relevant for the biasing of digit line 215-a-5.

It is also possible to observe that thin film transistor 225-a-4.1 has a conductive channel having one end portion connected to the digit line 215-a-5 and the other end portion connected to the conductive line 351. Moreover, dummy pillar 320-13 is arranged above the thin film transistor 225-a-4.1, wherein one end portion of the dummy pillar 320-13 is connected to the conductive line 351, while the other end portion of the dummy pillar 320-13 is floating.

As explained with reference to FIG. 5, the conductive line 351 is coupled to the conductive line 340 (see the dashed line) by means of conductive via 345, conductive line 346 and conductive via 341: since the conductive line 351 is connected to the access voltage VPP (for example, equal to +3.5 Volt), when the thin film transistor 225-a-4.1 is activated (by suitably setting the activation voltage of the gate line 310-a-4), the voltage value of the digit line 215-a-5 is also set equal to the access voltage VPP (for example, equal to +3.5 Volt).

The above considerations of FIG. 6A about thin film transistor 225-a-4.1 under dummy pillar 320-13 are applicable also to thin film transistors under dummy pillars 320-4, 320-7, 320-10, so that the voltage value of the digit lines 215-a-2, 215-a-3, 215-a-4 may be set equal to the access voltage (for example, equal to +3.5 Volt), when the respective thin film transistor is activated by suitably driving the gate lines 310-a-1, 310-a-2, 310-a-3 to the activation voltage (for example equal to 2 Volts), respectively.

During access to a selected digit line, the selected digit line is biased to the desired access voltage (for example, equal to 3.5 volt) as described above, while other not selected digit lines are de-selected. Accordingly, when one of the thin film transistors 225-a-4.1, 225-a-4.2, 225-a-4.3, 225-a-4.4 is enabled, the others thin film transistors are disabled. For example, when gate line 310-a-4 (e.g., the gate of transistor 225-a-4.1 coupled between conductive line 351 and digit line 215-a-5) is biased to 5 Volt in order to bias digit line 215-a-5 to 3.5 Volt (see FIG. 7A, top-left), gate lines 310-a-1, 310-a-2 and 310-a-3 may be biased to a deactivation voltage (for example equal to −3.5 Volt) to disable thin film transistors coupled between respective conductive lines 350, 352, 353 and respective digit lines 215-a-3, 215-a-4, 215-a-2 (see FIG. 7A, bottom-left for gate line 310-a-1 and digit line 215-a-4).

FIG. 6B shows a side section view of the second area 302 relative to a cut plane E-E as shown in FIG. 5, wherein some elements are removed for clarity.

In particular, FIG. 6B shows more in detail the structure of the fourth group of the digit line driver for setting the voltage value of the digit line 215-a-5 extending in the second area 302 to the inhibit voltage (for example, a ground reference voltage equal to 0 Volt).

Thin film transistors 225-b-1.1, 225-b-1.2, 225-b-1.3, 225-b-1.4 are examples of thin film transistors of the second plurality of film thin transistors arranged in the second area 302 of the memory device 200 and dummy pillars 320-17, 320-18, 320-19, 320-20 are examples of dummy pillars of the second plurality of dummy pillars arranged in the second area 302 of the memory device 200.

Thin film transistor 225-b-1.1 is interposed between dummy pillar 320-17 and digit line 215-a-5, thin film transistor 225-b-1.2 is interposed between dummy pillar 320-18 and digit line 215-a-4, thin film transistor 225-b-1.3 is interposed between dummy pillar 320-19 and digit line 215-a-3 and thin film transistor 225-b-1.4 is interposed between dummy pillar 320-20 and digit line 215-a-2. More in detail, thin film transistor 225-b-1.1 is electrically connected to dummy pillar 320-17, while dummy pillars 320-18, 320-19, 320-20 are floating so that they are not relevant for the biasing of digit line 215-a-5.

It is also possible to observe that thin film transistor 225-b-1.1 has a conductive channel having one end portion connected to the digit line 215-a-5 and the other end portion connected to the conductive element 360. Moreover, dummy pillar 320-17 is arranged above the thin film transistor 225-b-1.1, wherein one end portion of the dummy pillar 320-17 is connected to the conductive element 360, while the other end portion of the dummy pillar 320-17 is biased to the inhibit voltage (for example, a ground voltage) as explained with reference to FIG. 5: when the thin film transistor 225-b-1.1 is activated (by setting a deactivation voltage on the gate line 310-a-5, for example equal to 2 Volt), the voltage value of the digit line 215-a-5 is also set equal to the inhibit voltage VSS (for example, a ground voltage equal to 0 Volt). In other words, the electrical path comprising the dummy pillar 320-17, the conductive element 360, thin film transistor 225-b-1.1 (driven by gate line 310-a-5) forms a portion (or a branch) of the digit line driver associated to digit line 215-a-5.

The above considerations of FIG. 6B about thin film transistor 225-b-1.1 under dummy pillar 320-17 are applicable also to thin film transistors under dummy pillars 320-32, 320-27, 320-22, so that the voltage value of the digit lines 215-a-2, 215-a-3, 215-a-4 may be set equal to the inhibit voltage VSS (for example, a ground voltage equal to 0 Volt), when the respective thin film transistor is activated by suitably driving the gate lines 310-a-8, 310-a-7, 310-a-6 to the activation voltage (for example equal to 2 Volts), respectively.

During access to a selected digit line, the selected digit line is biased to the desired access voltage VPP as described above, while other unselected digit lines are de-selected and biased to the inhibit voltage VSS (e.g., ground voltage) enabling the respective thin film transistor coupled to a dummy pillar that has the other end grounded. For example, when gate line 310-a-4 (e.g., the gate of transistor 225-a-4.1 coupled between conductive line 351 and digit line 215-a-5) is biased to 5 Volt (in order to bias digit line 215-a-5 to 3.5 Volt), gate line 310-a-5 is biased to −3.5 Volt in order to disable transistor 225-b-1.1 and gate lines 310-a-6, 310-a-7 and 310-a-8 are biased for example to 2 Volt in order to enable thin film transistors coupled between respective digit lines 215-a-4, 215-a-3 and 215-a-2 and respective grounded dummy pillars 320-22, 320-27 and 320-32, so that the unselected digit lines are biased to the ground voltage (0 Volt).

FIG. 6C shows a side section view of the second area 302 relative to a cut plane F-F as shown in FIG. 5, wherein some elements are removed for clarity. In particular, FIG. 6C shows more in detail the portion of the digit line driver for driving digit line 215-a-5.

Thin film transistors 225-a-1.1, 225-a-2.1, 225-a-3.1, 225-a-4.1, 225-b-1.1, 225-b-2.1, 225-b-3.1, 225-b-4.1 are examples of thin film transistors of the second plurality of thin film transistors arranged in the second area 302 of the memory device 200 and dummy pillars 320-1, 320-5, 320-9, 320-13, 320-17, 320-21, 320-25, 320-29 are examples of dummy pillars of the second plurality of dummy pillars in the second area 302.

The digit line 215-a-5 extends along the y-direction until dummy pillar 320-13, so that thin film transistors 225-a-4.1, 225-b-1.1, 225-b-2.1, 225-b-3.1, 225-b-4.1 are interposed along the z-direction between digit line 215-a-5 and dummy pillars 320-13, 320-17, 320-21, 320-25, 320-29, respectively, while thin film transistors 225-a-1.1, 225-a-2.1, 225-a-3.1 have one end along the z-direction which is floating. Moreover, thin film transistor 225-a-4.1 is interposed along the z-direction between dummy pillar 320-13 and the digit line 215-a-5, wherein one end portion of the conductive channel of the thin film transistor 225-a-4.1 is connected to the digit line 215-a-5 and the other end portion is connected to the conductive line 351. Thin film transistor 225-b-1.1 is interposed between dummy pillar 320-17 and digit line 215-a-5, wherein one end portion of the conductive channel of the thin film transistor 225-b-1.1 is connected to the digit line 215-a-5 and the other end portion is connected to the conductive element 360. Thin film transistors 225-b-2.1, 225-b-3.1, 225-b-4.1 are interposed between dummy pillars 320-21, 320-25, 320-29, respectively.

Dummy pillar 320-13 is arranged above the thin film transistor 225-a-4.1 along the z-direction, wherein one end portion of the dummy pillar 320-13 is connected to the conductive line 351, while the other end portion of the dummy pillar 320-13 is floating.

Dummy pillar 320-17 is arranged above the thin film transistor 225-b-1.1 along the z-direction, wherein one end portion of the dummy pillar 320-17 is connected to the conductive element 360, while the other end portion of the dummy pillar 320-13 is connected to the inhibit voltage (for example, a ground voltage).

Considering the z-direction, the conductive line 340 is arranged at the lowest level, the digit line 215-a-5 is arranged at a level higher than the conductive line 340, and the conductive line 351 is arranged at a level higher than the digit line 215-a-5.

FIG. 6C shows two portions of the digit line driver along the plane y-z:

a portion of the digit line driver is implemented by the electrical path comprising the conductive line 340, conductive via 341, conductive line 346, conductive via 345, conductive line 351 and thin film transistor 225-a-4.1 under dummy pillar 320-13;

another portion of the digit line driver is implemented by the electrical path comprising the dummy pillar 320-17, conductive element 360 and thin film transistor 225-b-1.1 under the dummy pillar 320-17.

In one embodiment, at least one group includes two or more thin film transistors (out of the second plurality of thin film transistors) and includes two or more corresponding dummy pillars (out of the second plurality of dummy pillars), wherein each thin film transistor is serially connected to a respective dummy pillar, thus obtaining two or more serial connections, wherein two or more serial connections are connected in parallel to each other. In other words:
a first thin film transistor (out of the second plurality of thin film transistors) has one end portion connected to a digit line and the other end portion coupled to a first dummy pillar (out of the second plurality of dummy pillars);
a second thin film transistor (out of the second plurality of thin film transistors) has one end portion connected to the same digit line and the other end portion coupled to a second dummy pillar (out of the second plurality of dummy pillars);
and so on for other thin film transistors out of the second plurality of thin film transistors and other dummy pillars out of the second plurality of dummy pillars;

Moreover, the other end portion of the first dummy pillar, second dummy pillar, . . . are electrically connected to the inhibit voltage (for example, the ground voltage).

In this way the driving capability of the digit line to the inhibit voltage (for example, the ground reference voltage) is increased, because two or more thin film transistors contribute to generate simultaneously the current for setting the voltage value of the digit line to the inhibit voltage.

In another embodiment, at least one group includes two or more thin film transistors (out of the second plurality of thin film transistors) connected in parallel each other, that is:
a first thin film transistor (out of the second plurality of thin film transistors) has one end portion connected to a digit line and the other end portion biased to a access voltage VPP;
a second thin film transistor (out of the second plurality of thin film transistors) has one end portion connected to the same digit line and the other end portion biased to the access voltage VPP;
and so on for other thin film transistors out of the second plurality of thin film transistors.

In this way the driving capability of the digit line to the access voltage VPP (is increased, because two or more thin film transistors contribute to generate simultaneously the current for setting the voltage value of the digit line to the access voltage VPP.

FIG. 7A-7B show electrical schemes of the portion of the digit line driver comprising the second plurality thin film transistors sharing the same conductive line 340.

The electrical schemes of FIG. 7A-7B are implemented in the second area with the structure illustrated in FIG. 5, 6A, 6B, 6C above.

FIG. 7A shows the electrical schemes of the digit line driver using positive polarity, wherein the voltage value of the selected digit line 215-a-5 is set to the access voltage VPP (for example equal to +3.5 Volt), while the voltage value of other unselected digit lines 215-a-4, 215-b-5, 215-b-4 is set to the inhibit voltage VSS (for example a ground reference equal to 0 Volt).

The electrical scheme on top-left of FIG. 7A is implemented with thin film transistors 225-a-4.1 and 225-b-1.1 and dummy pillar 320-17, which have the function to bias the digit line 215-a-5 as explained above with reference to FIGS. 5 and 6C.

It is supposed that the access voltage VPP is equal to +3.5 Volt, the inhibit voltage is equal to 0 Volt, the activation voltage is equal to +5 Volt and the deactivation voltage is equal to −3.5 Volt.

When selecting digit line 215-a-5 (see the scheme on top-left of FIG. 7A), gate line 310-a-4 is set to +5 Volt in order to enable thin film transistor 225-a-4.1 (i.e. switch on), while gate line 310-a-5 is set to −3.5 Volt in order to disable thin film transistor 225-b-1.1 (i.e. switch off): in this way the access voltage VPP=3.5 Volt is transferred to the digit line 215-a-5, which is thus biased to 3.5 Volt.

The electrical scheme of the digit line driver on bottom-left of FIG. 7A is implemented, alternatively, with:
thin film transistor under dummy pillar 320-4, thin film transistor under dummy pillar 320-32 and dummy pillar 320-32, which have the function to bias the digit line 215-a-2;
thin film transistor under dummy pillar 320-7, thin film transistor under dummy pillar 320-27 and dummy pillar 320-27, which have the function to bias the digit line 215-a-3;
thin film transistor under dummy pillar 320-10, thin film transistor under dummy pillar 320-22 and dummy pillar 320-22, which have the function to bias the digit line 215-a-4.

The above alternative schemes have in common to be coupled to the same conductive line 340 set to the access voltage VPP equal to +3.5 Volt, so that unselection of the digit line 215-a-2, 215-a-3, 215-a-4 is achieved by enabling thin film transistor coupled to the dummy pillar biased to the ground voltage. For example, let's suppose that the electrical scheme on bottom-left of FIG. 7A is implemented with thin film transistor under dummy pillar 320-4, thin film transistor under dummy pillar 320-32 and dummy pillar 320-32. The digit line 215-a-2 is unselected by biasing the digit line 215-a-2 to 0 Volt and this is achieved in the following way:
the gate line driving the thin film transistor under dummy pillar 320-4 is biased to −3.5 Volt, so that thin film transistor under dummy pillar 320-4 is disabled (i.e. switch off);
the gate line driving the thin film transistor under dummy pillar 320-32 is biased to 2 Volt, one end of thin film transistor under dummy pillar 320-32 is coupled to the inhibit voltage equal to 0 Volt and the other end of thin film transistor under dummy pillar 320-32 is connected to the digit line 215-a-2, so that thin film transistor under dummy pillar 320-32 is enabled (i.e. switch on) and the digit line 215-a-2 is biased to 0 Volt.

The electrical schemes of the digit line driver on top-right and bottom-right of FIG. 7A have in common that the access voltage VPP is supplied by a conductive line 340a, which can thus have a voltage value different from the voltage value set on the conductive line 340.

In particular:
the electrical scheme of the digit line driver on top-right share the same gate lines 310-a-4 and 310-a-5 of the digit line driver on top-left, so that gate line 310-a-4 is set to +5 Volt and gate line 310-a-5 is set to −3.5 Volt: in this case the unselection of the digit line 215-b-5 (not shown in FIG. 5) is achieved by setting the voltage of the conductive line 340a equal to 0 Volt in order to enable thin film transistor interposed between the digit line 215-b-5 and the dummy pillar coupled to the conductive line 340a;
the electrical scheme of the digit line driver on bottom-right share the same gate lines 310-a-1 and 310-a-8 of the digit line driver on bottom-left, so that gate line 310-a-1 is set to −3.5 Volt and gate line 310-a-8 is set to 2 Volt: in this case the unselection of the digit line 215-b-4 (not shown in FIG. 5) is achieved by enabling thin film transistor interposed between digit line 215-b-4 and the dummy pillar coupled to the inhibit voltage VSS equal to 0 Volt.

FIG. 7B shows a driving scheme using negative polarity, wherein the voltage value of the selected digit line 215-a-5 is set to a negative voltage (for example equal to −3.5 Volt), the voltage value of the unselected digit lines 215-a-4, 215-b-4 is set to 0 Volt and the voltage value of the unselected digit line 215-b-5 is floating.

The previous considerations about the scheme of FIG. 7A are applicable analogously to the scheme of FIG. 7B, with the difference that the access voltage VPP is equal to −3.5 Volt, so that the digit line 215-a-5 is biased to −3.5 Volt when selected.

Referring to FIG. 8, it shows a flowchart 400 of a method for driving a digit line in a memory device 100 according to examples disclosed above.

The flowchart 400 comprises steps 401 and 402.

Step 401 comprises providing a plurality of memory cells at cross-points of word lines, on a plurality of levels of a memory array 200, and a plurality of conductive pillars extending through the plurality of levels, wherein a plurality of thin film transistors are each coupled between a digit line and a respective pillar, wherein the plurality of memory cells and the plurality of thin film transistors are positioned in a first area 301 of the memory array, and wherein the digit line extends in the first area and at least partially in a second area 302 outside the first area.

Step 401 is followed by step 402 comprises selectively enabling a first thin film transistor, coupled between the digit line and an end portion of a pillar, to bias the digit line to an inhibit voltage applied to another end portion of the pillar, and a second thin film transistor, coupled between the digit line and a conductive line, to bias the digit line to an access voltage applied to the conductive line, wherein the first thin film transistor, the second thin film transistor and the pillar are positioned in the second area 302.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

1. A memory device comprising:
a plurality of pillars extending through a plurality of levels of a memory array;
one or more memory cells of the memory array coupled with a respective pillar and a respective word line at each level of the plurality of levels;
a digit line;
a plurality of thin film transistors (TFTs), each TFT being configured to selectively couple the digit line with a respective pillar, wherein the plurality of pillars, the one or more memory cells and the plurality of thin film transistors are positioned in a first area of the memory array, and wherein the digit line extends in the first area and at least partially in a second area (302) outside the first area; and
a driver for the digit line, the driver comprising a first TFT, a second TFT and a pillar, wherein the first TFT, the second TFT and the pillar are positioned in the second area.

2. The memory device of claim 1, wherein the digit line is coupled to the first TFT and to the second TFT.

3. The memory device of claim 1, wherein the first TFT is coupled between the digit line and an end portion of said pillar, another end portion of said pillar being configured to be coupled to a source of an inhibit voltage (VSS).

4. The memory device of claim 1, wherein the first TFT comprises a first gate terminal for driving the first TFT, the first gate terminal coupled to a first gate line in the second area in a second direction substantially orthogonal to a first direction of the digit line.

5. The memory device of claim 1, wherein the second TFT is coupled between the digit line and a conductive line configured to be biased to an access voltage (VPP).

6. The memory device of claim 5, wherein the second TFT comprises a second gate terminal for driving the second TFT, the second gate terminal coupled to a second gate line in the second area in a second direction substantially orthogonal to a first direction of the digit line.

7. The memory device of claim 1, comprising a further digit line, a further driver for the further digit line comprising a third TFT, a fourth TFT and a further pillar, the third TFT, the fourth TFT and the further pillar being positioned in the second area, wherein the third TFT comprises a third gate terminal for driving the third TFT, the third gate terminal coupled to a third gate line, the fourth TFT comprises a fourth gate terminal for driving the fourth TFT, the fourth gate terminal coupled to a fourth gate line, wherein the third TFT is coupled between the further digit line and an end portion of said further pillar, another end portion of said further pillar being configured to be coupled to a source of an inhibit voltage (VSS).

8. The memory device of claim 3, wherein the first TFT and said pillar form a first electrical path between the digit line and the source of the inhibit voltage, the memory device further comprising a third TFT and a further pillar coupled between the digit line and the source of the inhibit voltage, the third TFT and the further pillar forming a second electrical path in parallel connection to the first electrical path.

9. The memory device of claim 5, wherein the memory device further comprises a fourth TFT coupled between the digit line and the conductive line in parallel connection to the second TFT.

10. The memory device of claim 1, further comprising a gate line biasing circuit configured to drive a gate line coupled to the first and/or the second TFT, wherein the gate line biasing circuit is positioned in the second area.

11. The memory device of claim 1, wherein the second area is adjacent to the first area, the first area comprising active cells and the second area comprising inactive cells.

12. The memory device of claim 1, further comprising a voltage supply generator configured for generating an access voltage (VPP), wherein the voltage supply generator is arranged in a portion of the first area.

13. A method to drive a digit line in a memory device, the method comprising:
providing a plurality of memory cells at cross-points of word lines, on a plurality of levels of a memory array, and a plurality of conductive pillars extending through the plurality of levels, wherein a plurality of thin film transistors (TFTs) are each coupled between the digit line and a respective pillar, wherein the plurality of memory cells and the plurality of TFTs are positioned in a first area of the memory array, and wherein the digit line extends in the first area and at least partially in a second area outside the first area; and
selectively enabling a first TFT, coupled between the digit line and an end portion of a pillar, to bias the digit line to an inhibit voltage applied to another end portion of the pillar, and a second TFT, coupled between the digit line and a conductive line, to bias the digit line to an access voltage applied to the conductive line, wherein the first TFT, the second TFT and the pillar are positioned in the second area.

14. The method of claim 13, further including coupling another end portion of said pillar to a source of an inhibit voltage (VSS).

15. The method of claim 13, further including coupling a first gate line in the second area to a first gate terminal of the first TFT, wherein the first gate line extends in a second direction substantially orthogonal to a first direction of the digit line. 16 (Currently Amended) The method of claim 15, further including coupling a second gate line in the second area to a second gate terminal of the second TFT, wherein the second gate line extends in a second direction substantially orthogonal to a first direction of the digit line.

17. The method of claim 13, wherein the second area is adjacent to the first area, the first area comprising active cells and the second area comprising inactive cells.

18. A method of manufacturing a memory device, the method comprising:
forming a plurality of conductive word lines, electrically insulated from each other, in a plurality of levels;
forming a plurality of conductive pillars through the plurality of levels, the plurality of pillars comprising active pillars in a first active area of a memory array and dummy pillars in a second area of the memory array adjacent to the first active area;
forming memory cells at cross-points of word lines and the plurality of pillars;
forming a plurality of conductive digit lines, electrically insulated from each other, in the first active area and extending, at least partially, into the second area;
forming, in the first active area and in the second area, a plurality of thin film transistors (TFTs), each TFT in the first active area being coupled between a respective digit line and a respective pillar of the plurality of pillars; and
forming a digit line driver in the second area, the digit line driver comprising:
a first TFT coupled between a respective digit line and a respective dummy pillar having an end coupled to a source of a inhibit voltage (VSS); and
a second TFT coupled between the respective digit line and a respective conductive line coupled to an access voltage (VPP).

19. The method of claim 18, further comprising forming a plurality of conductive gate lines comprising:
first gate lines coupled to gate terminals of each TFT in the first active area; and
second gate lines selectively coupled to one of the first TFT or the second TFT in the second area.

20. The method according to claim 18, wherein forming the digit line driver comprises:
forming a conductive material in electrical contact of one end of a conductive channel of each TFT of the plurality of TFTs in the first active area and in the second area, and
patterning the conductive material so as to form the respective conductive line coupled to one end of a conductive channel of the second TFT, and conductive elements on respective ends of conductive channels of the first TFT and the each TFT in the first active area.
